(19) United States
(12) Patent Application Publication
(10) Pub. No.: US 2010/0051983 A1
(43) Pub. Date: Mar. 4, 2010

(54) POLARIZATION RECYCLING OPTICS FOR LEDS

(76) Inventor: Frank SHUM, Sunnyvale, CA (US)

Correspondence Address: Arent Fox LLP, 555 West Fifth Street, 48th Floor, Los Angeles, CA, 90013, US

(21) Appl. No.: 12/201,925

(22) Filed: Aug. 29, 2008

(51) Int. Cl. H01L 33/00

(52) U.S. Cl. 257/98; 257/E33.06

(57) ABSTRACT

An integrated multi-layer apparatus and method of producing the same is disclosed. The structure comprises an LED configured to emit first and second polarized light, and a polarizing layer configured to pass a first polarized light and reflect the second polarized light back to the LED, wherein the LED is further configured to randomly scatter the second polarized light reflected from the polarizing layer and redirect the scattered light back to the polarizing layer.

### FIELD

The present disclosure relates generally to the field of semiconductor light emitting devices, and more specifically, to polarization recycling optics for light emitting devices.

### BACKGROUND

Polarization of light is a property of waves which describes the orientation of the oscillations in the plane perpendicular to the wave's direction of travel. S and P polarization refer to the plane in which the electric field of a light wave is oscillating. The p-polarization refers to the polarization plane parallel to the polarization axis of the polarizer being used (“p” is for “parallel”). The s-polarization refers to the polarization plane perpendicular to the polarization axis of the polarizer. A linear polarizer, by design, polarizes light in the p-polarization.

One useful application of a polarized light source is for a liquid crystal display (LCD). A LCD works by passing one polarization and blocking the other polarization. By tuning the degree of polarization at each pixel of the LCD, the amount of light exiting can be modulated to form a gray scale image. The LCD requires only one polarization of light to enter and one polarization of light to exit the system. This is accomplished typically with an input and output polarizer. Light sources emit light randomly in all polarizations. The job of the input polarizer is to eliminate the unwanted polarization of light. Thus, at least 50% of the light is lost by the first polarizer. If a polarized light source is available, then the system can before more efficient with the potential to eliminate the input polarizer. A light emitting diode with a polarized output would be a particularly attractive choice because, among other features, they consume less energy and have good conversion efficiency as compared to conventional light sources such incandescent and fluorescent lamps.

### SUMMARY

In one aspect of the disclosure, an integrated multi-layer apparatus including an LED configured to emit light having first and second polarized light, wherein the first polarized light has a different polarization from the second polarized light, and a polarizing layer configured to pass the first polarized light and reflect the second polarized light back to the LED, wherein the LED is further configured to randomly scatter the second polarized light and redirect the scattered light back to the polarizing layer.

In another aspect of the disclosure, an integrated multi-layer apparatus includes an LED configured to emit light having first and second polarized light, wherein the first polarized light has a different polarization from the second polarized light, and a polarizing layer configured to pass the first polarized light and reflect the second polarized light back to the LED, wherein the LED further comprises a roughened surface and a back reflector.

In yet another aspect of the disclosure, an integrated multi-layer apparatus includes light emitting means for emitting light having first and second polarized light, wherein the first polarized light has a different polarization from the second polarized light, and polarizing means for passing the first polarized light and reflecting the second polarized light back to the light emitting means, wherein the light emitting means comprises means for randomly scattering the second polarized light and means for redirecting the scattered light back to the polarizing reflector.

In a further aspect of the disclosure, a method of emitting light from an integrated multi-layer structure having an LED and a polarizing layer, includes emitting light from the LED, the emitted light having first and second polarized light, wherein the first polarized light has a different polarization from the second polarized light, passing the first polarized light reaching the polarizing layer through the polarizing layer and reflecting the second polarized light reaching the polarizing layer back to the LED, randomly scattering the second polarized light reflected back to the LED, and redirecting the scattered light back to the polarizing layer.

It is understood that other aspects of the present disclosure will become readily apparent to those skilled in the art from the following detailed description, wherein it is shown and described only exemplary aspects of the disclosure by way of illustration. As will be realized, the disclosure includes other and different aspects and its several details are capable of modification in various other respects, all without departing from the spirit and scope of the present disclosure. Accordingly, the drawings and the detailed description are to be regarded as illustrative in nature and not as restrictive.

### BRIEF DESCRIPTION OF THE DRAWINGS

Various aspects of the present disclosure are illustrated by way of example, and not by way of limitation, in the accompanying drawings, wherein:

FIG. 1 is a cross-section view illustrating an example of an LED;

FIG. 2 is a cross-section view illustrating an example of an integrated multi-layer apparatus;

FIG. 3a is an illustration of an example of a multi-layer structure with a polarizing layer;

FIG. 3b is an illustration of an example of another multi-layer structure with a polarizing layer; and

FIG. 3c is an illustration of an example of yet another multi-layer structure with a polarizing layer.

### DETAILED DESCRIPTION

The detailed description set forth below in connection with the appended drawings is intended as a description of various aspects of the present disclosure and is not intended to represent all ways in which the present disclosure may be practiced. The detailed description may include specific details for the purpose of providing a thorough understanding of the present disclosure; however, it will be apparent to those skilled in the art that the various aspects of the present disclosure may be practiced without these specific details. In some instances, well-known structures and components are summarily described and/or shown in block diagram form in order to avoid obscuring the concepts of the present disclosure.

Various aspects of this disclosure will be described in terms of an integrated multi-layer apparatus. As used herein, an integrated multi-layer apparatus is intended to cover a structure having multiple layers. Each layer of the apparatus may itself comprise several layers or sub-layers. By way of example, an integrated multi-layer apparatus may include an LED layer having an active region sandwiched between two oppositely doped epitaxial layers all of which are formed on a growth substrate. A polarizing layer formed on the LED may include several layers of material deposited onto a substrate such as glass. In other words, the term “layer” used throughout this disclose does not necessarily denote a homogeneous layer of material.

As those skilled in the art will readily appreciate, when a layer is referred to as being “on” another layer, it can be directly on the other layer or intervening layers may be present. For instance, the preceding reference to a polarizing layer on an LED does not preclude intervening layers between the two. In one configuration of a multi-layer apparatus discussed below, a refracting layer may be formed between the LED and the polarizing layer. This configuration may be modified by forming a beam shaping layer between the refracting layer and the polarizing layer. Alternatively, the apparatus may be formed with the polarizing layer between the refracting layer and the beam shaping layer.

The “integration” of these layers into the apparatus means that the layers are formed together by suitable means, now known or later discovered. By way of example, the LED may be grown on a substrate and the polarizing layer may be adhered, bonded or otherwise applied to the LED, either directly or through an intervening layer (e.g., refracting layer).

Various aspects of an integrated multi-layer apparatus are described herein with reference to cross-sectional view illustrations that are conceptual in nature. Various layers of the apparatus should not be construed as limited to the particular configuration shown in the drawings. By way of example, the “layers” of an integrated multi-layer apparatus are shown with discrete physical boundaries. However, in practice, a concentration gradient may exist across the physical boundaries between layers with the material from one layer penetrating the material of adjacent layers in either a controlled or random fashion. Thus, the layers illustrated in the drawings are conceptual in nature and their shapes are not intended to illustrate the precise shape of a layer of an apparatus and are not intended to limit the scope of the invention.

Those skilled in the art will further appreciate that relative terms such as “top” or “bottom” (and similar terms) may be used herein to describe a relationship between layers. Notwithstanding the use of such terms, those skilled in the art will readily understand that the concepts presented throughout this disclosure are intended to extend to different orientations of an integrated multi-layer apparatus in addition to the orientation depicted in the drawings.

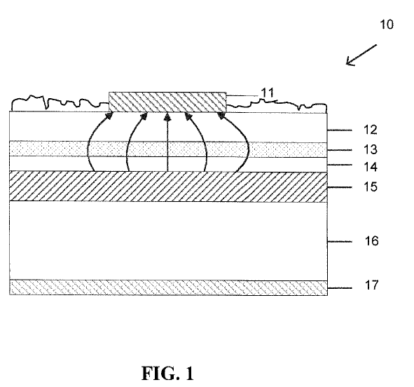

Turning to FIG. 1, an LED with a vertical structure is shown. However, as those skilled in the art will readily appreciate, the various aspects presented throughout this disclosure are likewise applicable to other LED structures, as well as other light emitting semiconductors, now known or later discovered. Accordingly, any reference to a vertical structure LED is intended only to illustrate various aspects, with the understanding that such aspects have a wide range of applications.

FIG. 1 is a cross-section view illustrating an example of an LED. An LED is a semiconductor material impregnated, or doped, with impurities. These impurities add “electrons” and “holes” to the semiconductor, which can move in the material relatively freely. Depending on the kind of impurity, a doped region of the semiconductor can have predominantly electrons or holes, and is referred respectively as n-type or p-type semiconductor regions, respectively. A reverse electric field is created at the junction between the two regions, which cause the electrons and holes to move away from the junction to form an “active region.”

The LED 10 is shown with an n-electrode 11 in contact with an n-type semiconductor layer 12 and a p-electrode 15 in contact with a p-type semiconductor layer 14. A thermally and/or electrically conductive substrate 16 supports the LED 10 structurally. A back reflector 17 may be formed on the bottom of the substrate 16. The LED may be fabricated using known processes with a suitable process being a fabrication process using chemical vapor deposition. The LED may be formed on a wafer and then singulated for mounting in a package. The growth substrate may remain as part of the singulated LED or the growth substrate may be fully or partially removed.

When a forward voltage sufficient to overcome the reverse electric field is applied across the p-n junction, via the p-electrode 15 and the n-electrode 11, electrons and holes are forced into an active region 13 and combine. When an electron combines with a hole, it falls to a lower energy level and releases energy in the form of light. If an incident angle of light at the interface between the n-type semiconductor layer 12 and the ambient air (or other encapsulating material) is greater than a critical angle in accordance with Snell's law, a portion of light generated inside the LED 10 device may get trapped inside the LED 10 due to total-internal-reflection (TIR). To increase the chance of light escaping from the LED, the n-type semiconductor layer 12 may be roughened. The roughened surface scatters the normal incident light in random direction and reduces the effects of TIR. The back reflector 17 may be provided at the bottom of the LED 10 for redirecting light emitted from the active region 13 back toward the top surface of the LED 10. Alternatively, or in addition to, one or more the sides of the LED 10 may also have a back reflector.

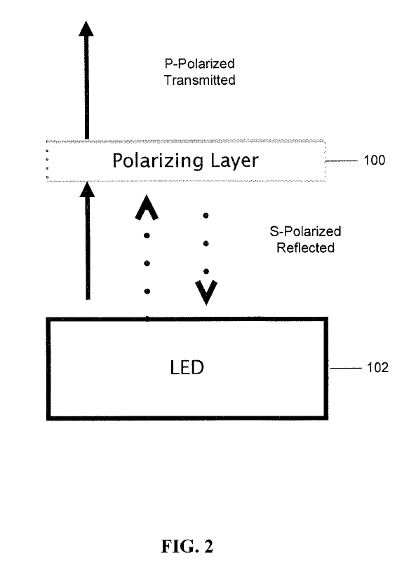

FIG. 2 is an abstract view illustrating an example of the functionality of an integrated multi-layer apparatus. The apparatus 99 includes a polarizing layer 100 on top of an LED 102 wherein the entire apparatus can be fabricated at an integrated circuit and/or at a wafer level. The LED 102 may be implemented as described above in connection with FIG. 1, or with some other suitable light emitting structure. The polarizing layer may include a thin-film polarizing reflector comprising several layers of material deposited onto a substrate (e.g., glass) by a physical vapor deposition process such as evaporative or sputter deposition or a chemical process such as chemical vapor deposition. An example of a polarizing reflector is manufactured by 3M under the trademark Vikuiti™ Dual Brightness Enhancement Films (DBEF). The LED 102 emits p-polarized and s-polarized light towards the polarization layer 100. The polarizing layer 100 transmits the p-polarized light and reflects the s-polarized light back towards the LED 102. The reflected s-polarized light gets randomly scattered by the roughened surface of the LED 102 so that a portion of light can be converted to p-polarized light (see FIG. 1). The randomly scattered light is then recycled back up from the LED 102 by the back reflector (see FIG. 1). The p-polarized recycled light then gets transmitted by the polarizing layer 100. The remaining s-polarized light gets reflected and the recycling process is repeated.

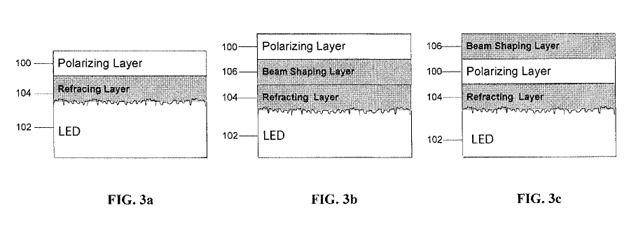

FIGS. 3a-3c are cross section views illustrating examples of various configurations for implementing an integrated multi-layer apparatus. Each example is shown with an LED 102. The light emission profile from an LED is non-directional and typically assumes a “lambertian” like profile where light is equally emitted into all directions. However, in various configurations, the polarizing layer 100 may only have a limited angle of acceptance. For such cases, a refracting layer 104 of about 0.5 micron thick may be used to minimize high angle light emitted from the LED 102. The refracting layer 104 has an index lower than the LED 102 and the polarizing layer 100. The refracting layer 104 and polarizing layer 100 may be part of the same substrate or become a single component. The refracting layer 104 may be a material such as air or some other suitable material. Furthermore, the refracting layer 104 should be large enough to ensure no direct coupling between the LED 102 and the polarizing layer 100.

The refracting layer 104, between the LED 102 and the polarizing layer 100, may have the following properties. The index of refraction of the refracting layer 104 is less than the index of refraction of the LED 102 and the index of refraction of the polarizing layer 100. In this configuration, the height of the refracting layer 104 is larger than 1 λ/nL to ensure no direct coupling between the LED 102 and the polarizing layer 100 takes place, where λ is the wavelength, and nL is the index of refraction of the refracting layer 104.

Turning to FIGS. 3b and 3c, a beam shaping layer 106 may be used to ensure light that is not within the angle of acceptance of the polarizing layer 100 does not escape from the apparatus. The beam shaping layer 106 may be an optical element or filter that passes an angular range of incident light and reflects light falling outside the angular range due to TIR. The optical element may be formed by depositing several layers of material deposited onto a substrate (e.g., glass) by a physical vapor deposition process such as evaporative or sputter deposition or a chemical process such as chemical vapor deposition. An example of such an optical element is a periodic prism structure manufactured by 3M under the trademark Vikuiti™ Brightness Enhancement Film (BEF). Other optical elements that may be used include periodic structures formed with a number of lenses, mirrors, prisms, or other optical components, or any combination thereof.

Referring to FIG. 3b, the LED 102 is topped with a refracting layer 104, and then the beam shaping layer 106 is placed on top of the refracting layer 104. A polarizing layer 100 is then situated on top of the beam shaping layer 106.

In the structure shown in FIG. 3b, light generated by the LED of 102 gets refracted through the refracting layer 104 with the high angular light getting reflected back by the beam shaping layer 106 through the refracting layer 104 to the LED 102. Then the reflected light is randomly scattered by the roughened surface of the LED 102 and reflected by the back reflector (see FIG. 1). The light reflected by the back reflector is recycled back up from the LED 102 through the refracting layer 104 to the beam shaping layer 106. The recycling of light enables more light to pass through the beam shaping layer 106 to the polarizing layer 100. At the polarizing layer, s-polarized light gets reflected back and later gets recycled back up. The p-polarized light gets emitted outwards which is expected to be of a brighter quality due to the recycling that was done by the beam shaping layer 106 and the polarizing layer 100. The s-polarization and p-polarization may be interchanged with one another.

Turning to FIG. 3c, the LED 102 is topped with a refracting layer 104, and a polarizing layer 100 is on top of the refracting layer 104. A beam shaping layer 106 is then situated on top of the polarizing layer 100.

In the structure of FIG. 3c, light generated by the LED 102 gets refracted through the refracting layer 104 to the polarizing layer 100. At the polarizing layer 100, p-polarized light is passed to the beam shaping optics layer 106 and s-polarized light is reflected back through the refracting layer 104 to the LED 102. The reflected light is randomly scattered by the roughened surface of the LED and reflected upward by the back reflector (see FIG. 1). The light reflected by the back reflector is recycled back up from the LED 102 through the refracting layer 104 to the polarizing layer 100, where p-polarized light is passed to the beam shaping optics layer 106 and s-polarized light is reflected. The recycling of light in this fashion allows more light to pass to the beam shaping layer 106. At the beam shaping layer 106, high angle light gets reflected while light within a specified angular range gets emitted from the apparatus. Because of the refraction provide by the refracting layer 104, more light should fall within the specified angular range of the beam shaping layer 106. The light that is reflected by the beam shaping optics layer 106 gets recycled is much the same way as described earlier in connection with FIG. 3b.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112, sixth paragraph, unless the element is expressly recited using the phrase “means for” or, in the case of a method claim, the element is recited using the phrase “step for.”

What is claimed is:

1. An integrated multi-layer apparatus, comprising:
an LED configured to emit light having first and second polarized light, wherein the first polarized light has a different polarization from the second polarized light; and
a polarizing layer configured to pass the first polarized light and reflect the second polarized light back to the LED;
wherein the LED is further configured to randomly scatter the second polarized light reflected from the polarizing layer and redirect the scattered light back to the polarizing layer.

2. The apparatus of claim 1 wherein the LED further comprises a roughened surface to randomly scatter the second polarized light reflected from the polarizing layer.

3. The apparatus of claim 1 wherein the LED further comprises a back reflector to redirect the scattered light back to the polarizing layer.

4. The apparatus of claim 1 further comprising a refracting layer between the polarizing layer and the LED, wherein the refracting layer comprises an index of refraction lower than the index of refraction of the LED and the polarizing layer.

5. The apparatus of claim 4 wherein the refracting layer comprises air.

6. The apparatus of claim 1 further comprising a beam shaping layer arranged with the LED and the polarizing layer.

7. The apparatus of claim 6 wherein the beam shaping layer is between the LED and the polarizing layer.

8. The apparatus of claim 6 wherein the polarizing layer is between the LED and the beam shaping layer.

9. The apparatus of claim 6 wherein the beam shaping layer comprises periodic optical structures.

10. The apparatus of claim 9 wherein the periodic optical structures comprise at least one of a lens, mirror, or prism.

11. The apparatus of claim 1 further comprising a refracting layer arranged with the LED, the beam shaping layer, and the polarizing layer, wherein the refracting layer comprises an index of refraction lower than the index of refraction of the LED, the beam shaping layer, and the polarizing layer.

12. An integrated multi-layer apparatus, comprising:
an LED configured to emit light having first and second polarized light, wherein the first polarized light has a different polarization from the second polarized light; and
a polarizing layer configured to pass the first polarized light and reflect the second polarized light back to the LED;
wherein the LED further comprises a roughened surface and a back reflector.

13. The apparatus of claim 12 further comprising a refracting layer between the beam shaping layer and the LED, wherein the refracting layer comprises an index of refraction lower than the index of refraction of the LED and the polarizing layer.

14. The apparatus of claim 13 wherein the refracting layer comprises air.

15. The apparatus of claim 12 further comprising a beam shaping layer arranged with the LED and the polarizing layer.

16. The apparatus of claim 15 wherein the beam shaping layer is between the LED and the polarizing layer.

17. The apparatus of claim 15 wherein the polarizing layer is between the LED and the beam shaping layer.

18. The apparatus of claim 15 wherein the beam shaping layer comprises periodic optical structures.

19. The apparatus of claim 18 wherein the periodic optical structure comprise at least one of a lens, mirror, or prism.

20. The apparatus of claim 12 further comprising a refracting layer arranged with the LED, the beam shaping layer, and the polarizing layer, wherein the refracting layer comprises an index of refraction lower than the index of refraction of the LED, the beam shaping layer, and the polarizing layer.

21. An integrated multi-layer apparatus, comprising:
light emitting means for emitting light having first and second polarized light, wherein the first polarized light has a different polarization from the second polarized light; and
polarizing means for passing the first polarized light and reflecting the second polarized light back to the light emitting means;
wherein the light emitting means comprises means for randomly scattering the second polarized light and means for redirecting the scattered light back to the polarizing reflector means.

22. The apparatus of claim 21 wherein the light emitting means comprises an LED having a roughened surface, and wherein the means for randomly scattering the second polarized light comprises the roughened surface on the LED.

23. The apparatus of claim 21 wherein the light emitting means comprises an LED having a back reflector, and wherein the means for redirecting the scattered light back to the polarizing reflector means comprises the back reflector.

24. The apparatus of claim 21 further comprising refracting means for refracting the light emitted from the light emitting means, wherein the refracting means is between the light emitting means and the polarizing means, the refracting means having an index of refraction lower than the index of refraction of the light emitting means and polarizing means.

25. The apparatus of claim 24 wherein the refracting means comprises air.

26. The apparatus of claim 21 further comprising beam shaping means for passing a first portion of the light emitted from the light emitting means and reflecting a second portion of the light emitted from the light emitting means.

27. The apparatus of claim 26 wherein the beam shaping means is between the light emitting means and the polarizing means.

28. The apparatus of claim 26 wherein the polarizing means is between the light emitting means and the beam shaping means.

29. The apparatus of claim 26 wherein the beam shaping means comprises periodic optical structures.

30. The apparatus of claim 29 wherein the periodic optical structures comprise at least one of a lens, mirror, or prism.

31. The apparatus of claim 21 further comprising refracting means for refracting the light emitted from the light emitting means, wherein the refracting means is arranged with the light emitting means, the beam shaping means and the polarizing means, wherein the refracting means comprises an index of refraction lower than the index of refraction of the light emitting means, the beans shaping means and the polarizing means.

32. A method of emitting light from an integrated multi-layer structure having an LED and a polarizing layer, the method comprising:
emitting light from the LED, the emitted light having first and second polarized light, wherein the first polarized light has a different polarization from the second polarized light;
passing the first polarized light reaching the polarizing layer and reflecting the second polarized light reaching the polarizing layer back to the LED;
randomly scattering the second polarized light reflected back to the LED by the polarizing layer; and
redirecting the scattered light back to the polarizing layer.

33. The method of claim 32 wherein the LED comprises a roughened surface, and wherein the second polarized light reflected back to the LED is scattered by the roughened surface.

34. The method of claim 32 wherein the LED comprises a back reflector, and wherein the scattered light is redirected back to the polarizing layer by the back reflector.

35. The method of claim 32 further comprising refracting the light emitted from the LED.

36. The method of claim 35 wherein the light emitted from the LED is refracted by passing the emitted light through air.

37. The method of claim 32 further comprising passing a first portion of the light emitted from the LED and reflecting a second portion of the light emitted from the LED back to the LED, wherein the first portion of the emitted light is within an angular range and the second portion of the emitted light is outside the angular range.

38. The method of claim 37 wherein the first portion of the light emitted from the LED is passed and the second portion of the light emitted from the LED is reflected by a beam shaping layer.

39. The method of claim 38 wherein the integrated multi-layer apparatus further comprises a refracting layer arranged with the LED, the beam shaping layer, and the polarizing layer, wherein the refracting layer comprises an index of refraction lower than the index of refraction of the LED.

40. The method of claim 37 wherein the first portion of the light emitted from the LED is passed to the polarizing layer.

41. The method of claim 37 wherein the first and second portions of the emitted light comprises the first polarized light passed by the polarizing layer.
